(19) United States
(12) Patent Application Publication
(10) Pub. No.: US 2025/0046736 A1
(43) Pub. Date: Feb. 6, 2025

(54) WAFFLE-SHAPED RADIO FREQUENCY (RF) SWITCH

(71) Applicant: QUALCOMM Incorporated, San Diego, CA (US)

(72) Inventor: Woojin CHOI, San Diego, CA (US)

(21) Appl. No.: 18/362,831

(22) Filed: Jul. 31, 2023

(51) Int. Cl. H01L 23/66; H04B 1/44

(52) U.S. Cl. CPC H01L 23/66; H04B 1/44; H01L 2223/6616; H01L 2223/6644

(57) ABSTRACT

A radio frequency (RF) switch is described. The RF switch includes a two-dimensional (2D) gate array surrounding source/drain regions and drain/source regions. The RF switch also includes backside source/drain contacts coupled to the source/drain regions at a backside of the 2D gate array. The RF switch further includes backside metallization layers coupled to the backside source/drain contacts. The RF switch also includes frontside drain/source contacts coupled to the drain/source regions at a frontside, opposite the backside, of the 2D gate array. The RF switch further includes frontside metallization layers coupled to the frontside drain/source contacts.

### TECHNICAL FIELD

The present disclosure relates to integrated circuits (ICs). More specifically, the present disclosure relates to a waffle-shaped radio frequency (RF) switch.

### BACKGROUND

The design complexity of mobile radio frequency (RF) chips (e.g., mobile RF transceivers) is complicated by added circuit functions for supporting communications enhancements. Designing mobile RF transceivers may include using semiconductor on insulator technology. Semiconductor on insulator (SOI) technology replaces conventional semiconductor (e.g., silicon) substrates with a layered semiconductor-insulator (e.g., buried oxide (BOX) layer)—semiconductor substrate for reducing parasitic device capacitance and improving performance. For example, high performance complementary metal oxide semiconductor (CMOS) radio frequency (RF) switch technologies are currently manufactured using SOI substrates.

In practice, switch area reduction is a principal factor in the design of RF switches. In fact, there is a desire in the industry to reduce the size of an RF chip package without compromising performance of the RF switches. The traditional RF switch structure has not changed from a line-shape interdigitated transistor with multiple fingers. This structure is a one-dimensional array of gates. Conventional solutions for reducing the size of RF switches involve reducing a gate-to-gate pitch, resulting in a total area reduction. A solution for reducing the size of the RF chip package without compromising the performance of the RF switches is desired.

### SUMMARY

A radio frequency (RF) switch is described. The RF switch includes a two-dimensional (2D) gate array surrounding source/drain regions and drain/source regions. The RF switch also includes backside source/drain contacts coupled to the source/drain regions at a backside of the 2D gate array. The RF switch further includes backside metallization layers coupled to the backside source/drain contacts. The RF switch also includes frontside drain/source contacts coupled to the drain/source regions at a frontside, opposite the backside, of the 2D gate array. The RF switch further includes frontside metallization layers coupled to the frontside drain/source contacts.

A method of constructing a radio frequency (RF) switch is described. The method includes forming a two-dimensional (2D) gate array surrounding a plurality of source/drain regions and a plurality of drain/source regions. The method also includes forming backside source/drain contacts coupled to the plurality of source/drain regions at a backside of the 2D gate array. The method further includes forming backside metallization layers coupled to the backside source/drain contacts. The method also includes forming frontside drain/source contacts coupled to the plurality of drain/source regions at a frontside, opposite the backside, of the 2D gate array. The method further includes forming frontside metallization layers coupled to the frontside drain/source contacts.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a wireless device having a wireless local area network module and a radio frequency (RF) front end module for a chipset, including waffle-shaped radio frequency (RF) switches, according to various aspects of the present disclosure.

FIG. 2 shows a cross-sectional view of a radio frequency (RF) integrated circuit (RFIC), including an RF silicon on insulator (SOI) device, which may be used to implement a waffle-shaped radio frequency (RF) switch, according to various aspects of the present disclosure.

FIG. 3 is a block diagram illustrating an overhead view of a conventional radio frequency (RF) switch structure, having line-shaped, interdigitated transistors with multiple fingers.

FIG. 4 is a block diagram illustrating an overhead view of a radio frequency (RF) switch field effect transistor (FET), having a waffle-shape, in accordance with various aspects of the present disclosure.

FIGS. 5A-5C are block diagrams illustrating perspective views and a cross-sectional view of the waffle-shaped radio frequency (RF) switch field effect transistor (FET) of FIG. 4, in accordance with various aspects of the present disclosure.

FIGS. 6A and 6B are schematic diagrams illustrating an overhead view and an enlarged overhead view of a waffle-shaped radio frequency (RF) switch field effect transistor (FET), in accordance with various aspects of the present disclosure.

FIG. 7 is a process flow diagram illustrating a method for constructing a radio frequency (RF) switch having a waffle-shape, according to various aspects of the present disclosure.

FIG. 8 is a block diagram showing an exemplary wireless communications system in which a configuration of the present disclosure may be advantageously employed.

FIG. 9 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile radio frequency (RF) chips (e.g., mobile RF transceivers) have migrated to a deep sub-micron process node due to cost and power consumption considerations. Designing mobile RF transceivers may include using semiconductor on insulator technology. Semiconductor on insulator (SOI) technology replaces conventional silicon substrates with a layered semiconductor-insulator (e.g., a buried oxide (BOX) layer)—semiconductor substrate for reducing parasitic device capacitance and improving performance. The active devices on the SOI layer may include high performance complementary metal oxide semiconductor (CMOS) transistors. For example, high performance CMOS RF switch technologies are currently manufactured using SOI substrates.

An RF front end (RFFE) may rely on these high-performance CMOS RF switch technologies for successful operation of the high-performance CMOS RF switch technologies. A process for fabricating an RFFE, therefore, involves the costly integration of an SOI wafer for supporting these high-performance CMOS RF switch technologies. In practice, switch area reduction is a principal factor in the design of RF switches. In fact, there is a desire in the industry to reduce the size of an RF chip package without compromising performance of the RF switches.

A traditional RF switch structure has not changed from a line-shape interdigitated transistor with multiple fingers. This RF switch structure is composed of a one-dimensional array of gates. Conventional solutions for reducing the size of RF switches involve reducing a gate-to-gate pitch, resulting in a total area reduction. Additionally, the traditional RF switch structure relies on two sides of the metal contacts, to the left and right of the gate for providing frontside metal contacts. The frontside metal contacts of the traditional RF switch structure fundamentally limits the interconnect and the path of current of the RF switch. A solution for reducing the size of the RF chip package without compromising the performance of the RF switches is desired.

Various aspects of the present disclosure provide techniques for a waffle-shaped radio frequency (RF) switch. The process flow for semiconductor fabrication of a waffle-shaped radio frequency (RF) switch may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to a substrate of a wafer that is not diced. Similarly, the terms “chip” and “die” may be used interchangeably.

Aspects of the present disclosure relate to a radio frequency (RF) switch, having a waffle-like shape. That is, various aspects of the present disclosure employ a waffle-shaped RF switch, including a two-dimensional (2D) gate array surrounding source/drain regions and drain/source regions. In this configuration, the 2D gate array includes a frontside and a backside opposite the frontside. The waffle-shaped RF switch includes backside source/drain contacts coupled to the source/drain regions at the backside of the 2D gate array. The RF switch further includes backside metallization layers coupled to the backside source/drain contacts. Additionally, the RF switch includes frontside drain/source contacts coupled to the drain/source regions at the frontside of the 2D gate array. The RF switch further includes frontside metallization layers coupled to the frontside drain/source contacts.

According to various aspects of the present disclosure, the waffle-shaped RF switch provides a new structure utilizing the four or more corners of contacts, which maximizes the efficiency of the total width of channels in a unit area. According to the waffle-shaped switch structure, a 2D array of gates is surrounded by contacts of source and drain regions. Because the frontside and backside contacts are separated, backside contacts and metallization processes engage in realizing this waffle-shaped switch structure. The proposed waffle-shaped switch structure enhances the usage of metal contacts resulting in a reduced area for the same total width. Additionally, using a proprietary process technology, the area of the RF switch can be significantly reduced (e.g., by 28%) compared to the reference line-shaped switch structure for the same total channel width. The area reduction can be further improved with optimizations on the backside process.

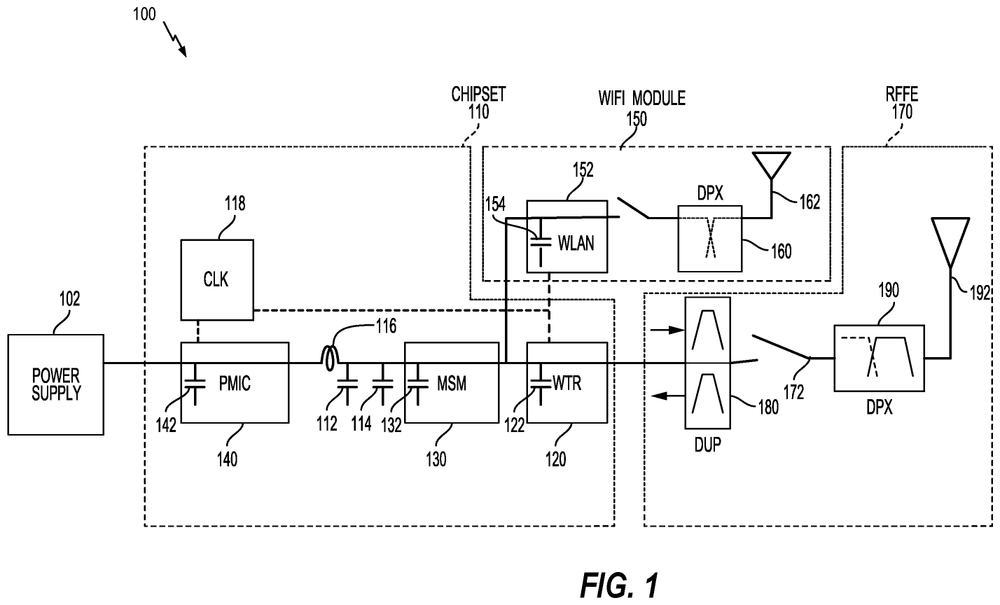

FIG. 1 is a schematic diagram of a wireless device 100 (e.g., a cellular phone or a smartphone) including a waffle-shaped radio frequency (RF) switch device, according to aspects of the present disclosure. The wireless device 100 has a wireless local area network (WLAN) (e.g., WIFI) module 150 and an RF front end module 170 for a chipset 110. The WIFI module 150 includes a first diplexer 160 communicably coupling an antenna 162 to a wireless local area network module (e.g., WLAN module 152). The RF front end module 170 includes the second diplexer 190 communicably coupling an antenna 192 to the wireless transceiver 120 (WTR) through a duplexer 180 (DUP). An RF switch 172 (e.g., a waffle-shaped radio frequency (RF) switch device) communicably couples the second diplexer 190 to the duplexer 180. The wireless transceiver 120 and the WLAN module 152 of the WIFI module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device includes a mobile RF transceiver to transmit and receive data for two-way communication. A mobile RF transceiver may include a transmit section for data transmission and a receive section for data reception. For data transmission, the transmit section may modulate an RF carrier signal with data to obtain a modulated RF signal, amplify the modulated RF signal using a power amplifier (PA) to obtain an amplified RF signal having the proper output power level, and transmit the amplified RF signal via the antenna 192 to a base station. For data reception, the receive section may obtain a received RF signal via the antenna and may amplify the received RF signal using a low noise amplifier (LNA) and process the received RF signal to recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in numerous ways to amplify the communication signals. Assorted options exist for fabricating the transistors that are configured to amplify the communication signals transmitted and received by the wireless transceiver 120.

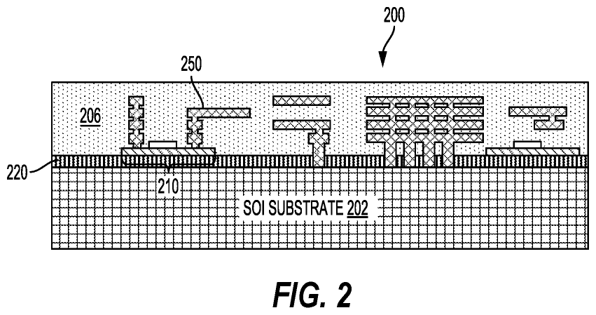

The wireless transceiver 120 and the RF front end module 170 may be implemented using semiconductor on insulator (SOI) technology for fabricating transistors of the wireless transceiver 120, which helps reduce high order harmonics in the RF front end module 170. SOI technology replaces conventional semiconductor substrates with a layered semiconductor-insulator (e.g., a buried oxide (BOX) layer)—semiconductor substrate for reducing parasitic device capacitance and improving performance. For example, high performance complementary metal oxide semiconductor (CMOS) radio frequency (RF) switch technologies are currently manufactured using SOI substrates. An active device, such as a waffle-shaped RF switch device is fabricated using SOI technology, for example, as shown in FIG. 2.

FIG. 2 shows a cross-sectional view of a radio frequency (RF) integrated circuit (RFIC) 200. As shown in FIG. 2, an RF silicon on insulator (SOI) device includes an active device 210 on a buried oxide (BOX) layer 220 supported by an SOI substrate 202 (e.g., a silicon wafer). The RF SOI device may be fabricated as a complementary metal oxide semiconductor (CMOS) transistor using a CMOS process. The RF SOI device also includes interconnects 250 coupled to the active device 210 within a first dielectric layer 206. In this configuration, a parasitic capacitance of the RF SOI device is proportional to a thickness of the BOX layer 220, which determines the distance between the active device 210 and the SOI substrate 202.

The active device 210 on the BOX layer 220 may be a CMOS transistor. For example, high performance CMOS RF switch technologies are currently manufactured using SOI substrates. The RFFE 170 (FIG. 1) may rely on these high-performance CMOS RF technologies for successful operation. A process for fabricating the RFFE 170, therefore, involves integration of an SOI wafer to support these high-performance CMOS RF switch technologies. Furthermore, support for future RF performance enhancements involves increased device isolation while reducing RF loss. The RF integrated circuit 200 may be used to implement the RFFE 170. For example, the active device 210 may be a switch field effect transistor (FET) of the RF switch 172 of the RFFE 170, such as a waffle-shaped RF switch device, according to various aspects of the present disclosure.

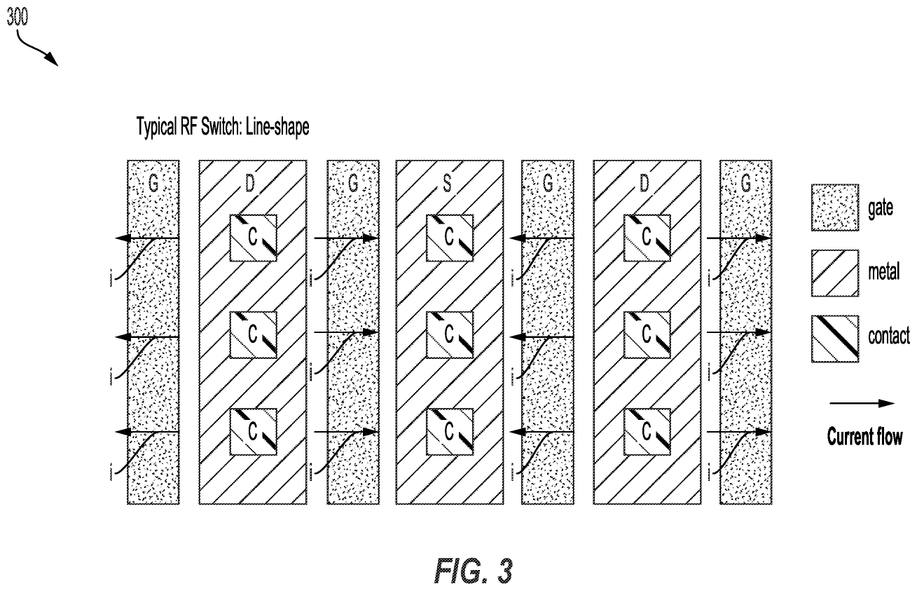

FIG. 3 is a block diagram illustrating an overhead view of a conventional radio frequency (RF) switch structure, having line-shaped, interdigitated transistors with multiple fingers. In this example, an RF switch structure 300 is composed of line-shaped source(S) regions and drain (D) regions interdigitated between gate (G) regions to provide an interdigitated transistor structure. Additionally, the RF switch structure 300 relies on two sides of metal contacts (C), to the left and right of the gate (G) region, for providing frontside metal contacts. The frontside metal contacts C of the traditional, RF switch structure 300 fundamentally limit the interconnect and the path of current (i) of the RF switch structure 300.

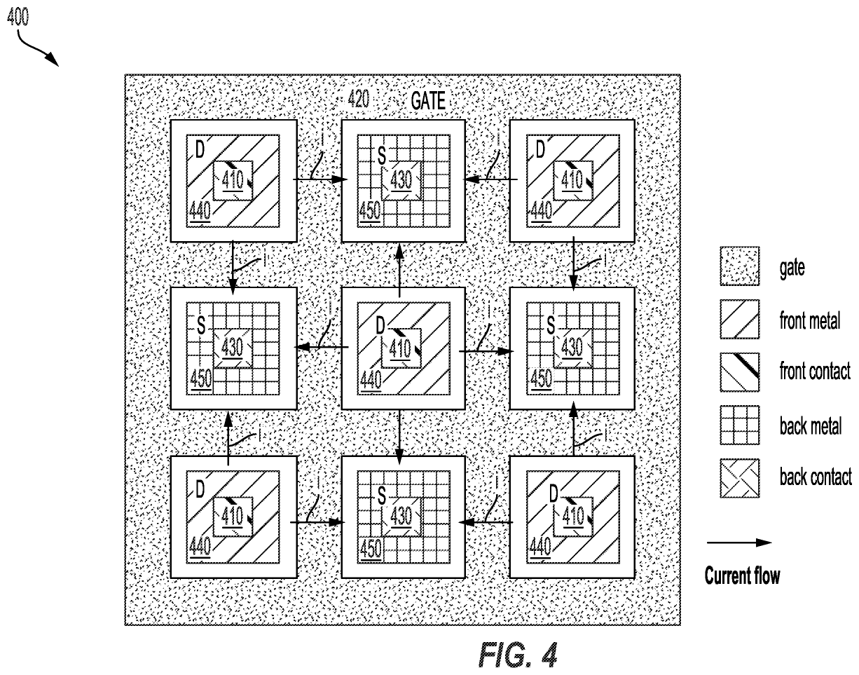

In practice, switch area reduction is a principal factor in the design of RF switches. In fact, there is a desire in the industry to reduce the size of an RF chip package without compromising performance of the RF switches. As shown in FIG. 3, the traditional, RF switch structure 300 has not changed from a line-shaped interdigitated transistor with multiple fingers. This structure is a one-dimensional array of gates G. Conventional solutions to reducing the size of an RF switch structure involve reducing a gate-to-gate pitch, resulting in a total area reduction. A solution for reducing the size of the RF chip package without compromising the performance of the RF switches is provided by a waffle-shaped RF switch, for example, as shown in FIG. 4.

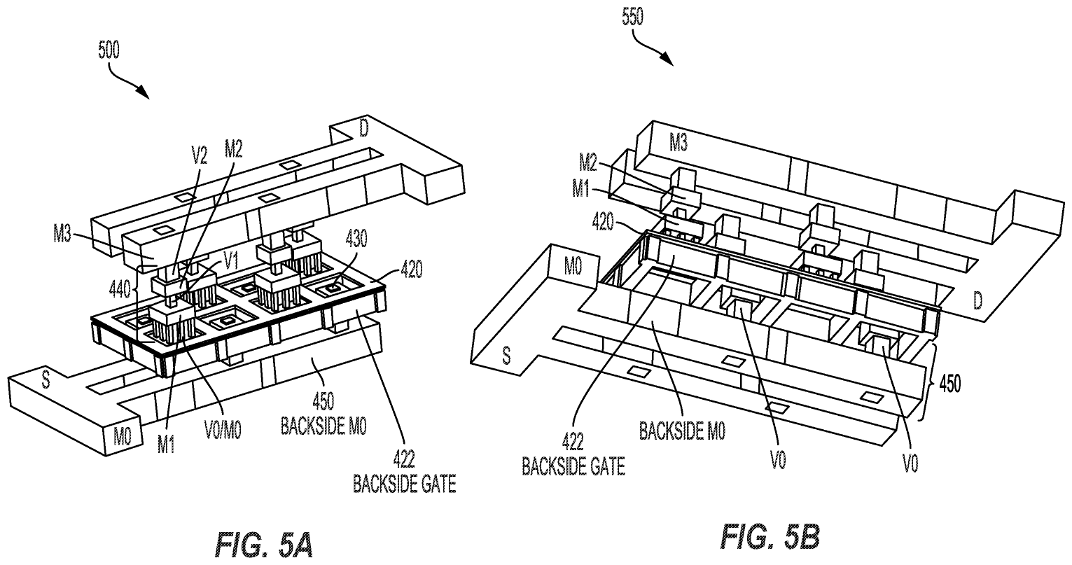

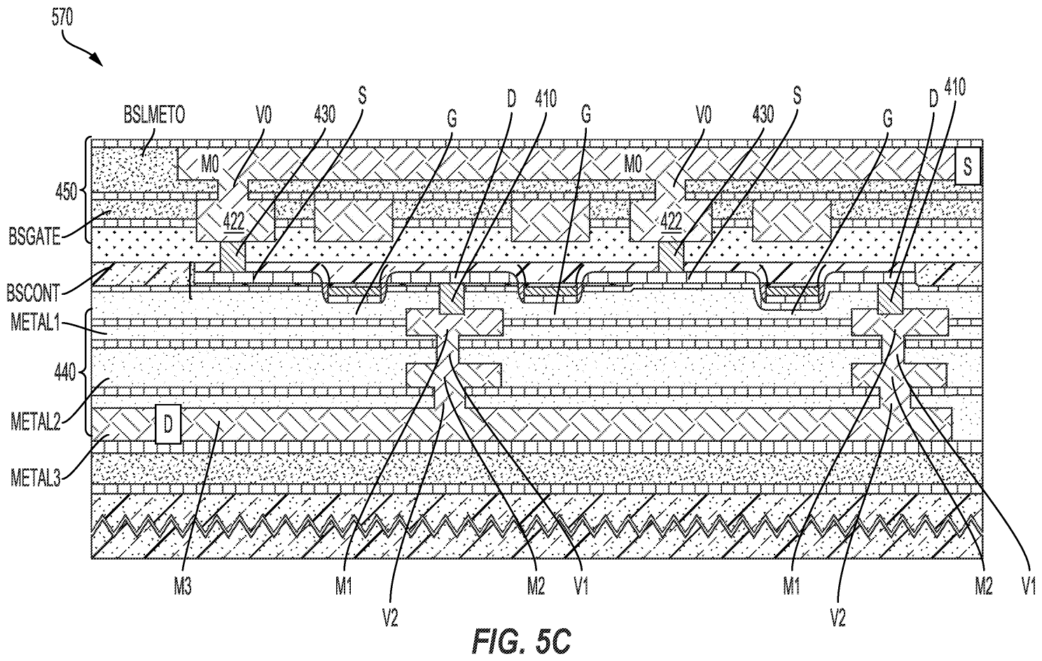

FIG. 4 is a block diagram illustrating an overhead view of a radio frequency (RF) switch field effect transistor (FET), having a waffle-shape, in accordance with various aspects of the present disclosure. As shown in FIG. 4, a waffle-shaped RF switch 400 includes a 2D gate array 420 surrounding source(S) regions and drain (D) regions. In this configuration, the 2D gate array 420 includes a frontside (shown) and a backside (not show) opposite the frontside. Based on this arrangement of the 2D gate array 420 surrounding the source(S) regions and drain (D) regions, a current (i) flows from front to back or vice versa, depending on whether the source(S) regions or drain (D) regions are contacted at the frontside or the back side of the 2D gate array 420, as further illustrated in FIGS. 5A-5C.

In the example of FIG. 4, the waffle-shaped RF switch 400 includes backside source contacts 430 coupled to the source(S) regions at the backside of the 2D gate array 420. Additionally, the waffle-shaped RF switch 400 includes frontside drain contacts 410 coupled to the drain (D) regions at the frontside of the 2D gate array 420. As shown in FIG. 4, each of the frontside drain contacts 410 and the backside source contacts 430 are surrounded by the 2D gate array 420. In this example, the frontside drain contacts 410 are contacted to frontside metallization layers 440, and the backside source contacts 430 are contacted to backside metallization layers 450 (e.g., middle-of-line (MOL) metallization layers), as further illustrated in FIG. 5A-5C.

FIGS. 5A-5C are block diagrams illustrating perspective views and a cross-sectional view of the waffle-shaped radio frequency (RF) switch field effect transistor (FET) of FIG. 4, in accordance with various aspects of the present disclosure.

FIG. 5A illustrates a perspective view of a frontside 500 of the waffle-shaped RF switch 400 of FIG. 4, according to various aspects of the present disclosure. In this example, the 2D gate array 420 is shown surrounding the backside source contacts 430 and coupled to a backside gate 422 and the backside metallization layers 450. Additionally, connections between the frontside metallization layers 440 to the frontside drain contacts 410 are further illustrated in FIG. 5A. In this example, the frontside metallization layers 440 are composed of middle-of-line (MOL) zero interconnect layers, including metal zero (M0) interconnect connections to the frontside drain contacts 410, followed by a zero via (V0) to back-end-of-line (BEOL) layers. The BEOL layers includes a first metal (M1) interconnect coupled to a first metal via (V1), and a second metal (M2) interconnect, followed by a second metal via (V2) connection to a third metal (M3) interconnect, which may be extended to outside bus lines. In this example, interconnects to drain (D) or source(S) regions are separated by the frontside metallization layers 440, or the backside metallization layers 450.

FIG. 5B illustrates a perspective view of a backside 550 of the waffle-shaped RF switch 400 of FIG. 4, according to various aspects of the present disclosure. In this example, the 2D gate array 420 is shown coupled to a backside gate 422 and the backside metallization layers 450. Additionally, connections between the backside metallization layers 450 to the backside source contacts 430 are further illustrated. In this example, the backside metallization layers 450 are composed of middle-of-line (MOL) metallization layers, including metal zero (M0) interconnects to the backside gate 422 through zero via (V0) interconnects. The M0 interconnects may be extended to outside bus lines, as further illustrated in FIG. 5C.

FIG. 5C illustrates a cross-sectional view 570 of the waffle-shaped RF switch 400 of FIG. 4, according to various aspects of the present disclosure. In this example, the 2D gate array 420 is further illustrated, including connections between the backside metallization layers 450 to the backside source contacts 430. Additionally, connections between the backside metallization layers 450 to the backside source contacts 430 are further illustrated. As shown in FIG. 5C, the waffle-shaped RF switch 400 is composed of a new structure utilizing four or more corners of contacts (see FIG. 4), which maximizes the efficiency of the total width of channels in a unit area. According to the structure of the waffle-shaped RF switch 400, the 2D gate array 420 surrounds the frontside drain contacts 410 to the drain (D) regions and backside source contacts 430 to the source(S) regions. Because the frontside drain contacts 410 and the backside source contacts 430 are separated, backside contacts and metallization processes participate in realizing the structure of the waffle-shaped RF switch 400 shown in the cross-sectional view 570 of FIG. 5C.

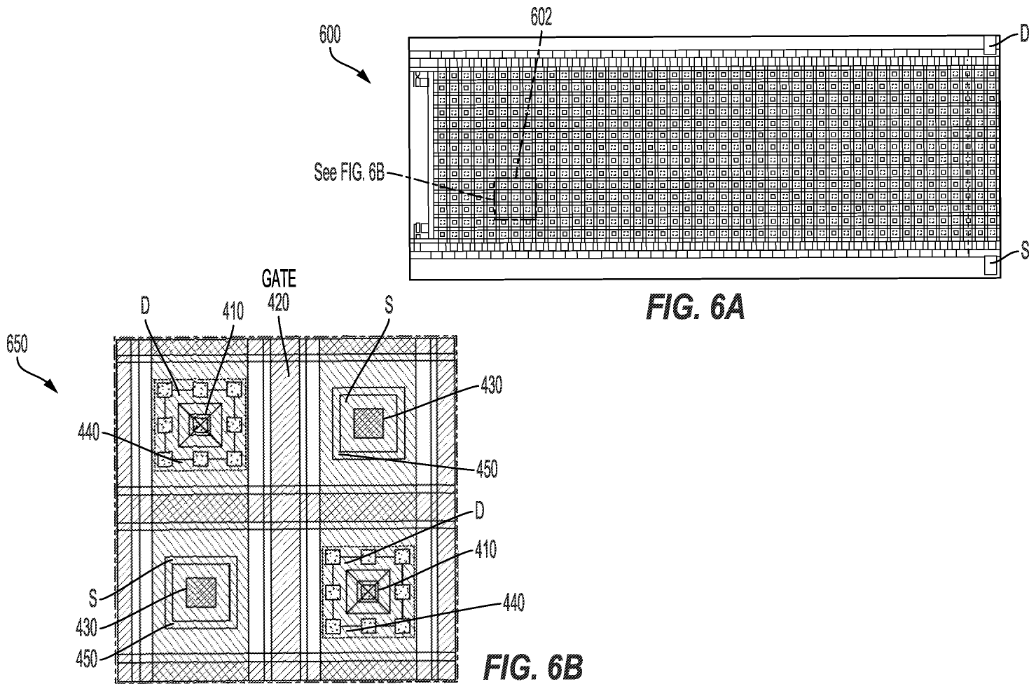

FIGS. 6A and 6B are schematic diagrams illustrating an overhead view and an enlarged overhead view of a waffle-shaped radio frequency (RF) switch field effect transistor (FET), in accordance with various aspects of the present disclosure. As shown in FIG. 6A, a waffle-shaped radio frequency (RF) switch field effect transistor (FET) 600 includes a highlighted portion 602, which is further illustrated in FIG. 6B.

FIG. 6B is a schematic diagram illustrating an enlarged view 650 of the waffle-shaped RF switch FET 600 shown in FIG. 6A, according to various aspects of the present disclosure. The portion of the waffle-shaped RF switch FET 600 in the enlarged view 650 is like the waffle-shaped RF switch 400 shown in FIG. 4 and is described using similar reference numbers. As shown in FIG. 6B, the waffle-shaped RF switch FET 600 includes a 2D gate array 420 surrounding source(S) regions and drain (D) regions. In this example, the waffle-shaped RF switch FET 600 includes backside source contacts 430 coupled to the source(S) regions at the backside of the 2D gate array 420.

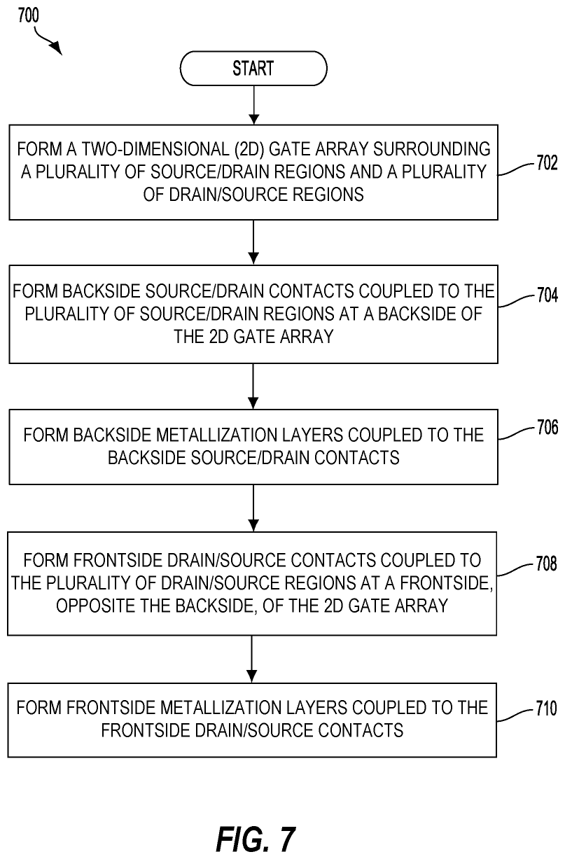

Additionally, the waffle-shaped RF switch FET 600 includes frontside drain contacts 410 coupled to the drain (D) regions at the frontside of the 2D gate array 420. In this example, the frontside drain contacts 410 are contacted to frontside metallization layers 440, and the backside source contacts 430 are contacted to backside metallization layers 450, as further illustrated in FIG. 5A-5C. The proposed structure of the waffle-shaped RF switch FET 600 shown in FIGS. 6A and 6B enhances the usage of the frontside drain contacts 410 and the backside source contacts 430, resulting in a reduced area for the same total width. Additionally, using a proprietary process technology for example, as shown FIG. 5C, the area of the waffle-shaped RF switch FET 600 is significantly reduced (e.g., by 28%) compared to the reference line-shaped, RF switch structure 300 shown in FIG. 3 for a same total channel width. The area reduction can be further improved with optimizations in the backside process. A method of constructing a waffle-shaped RF switch, according to various aspects of the present disclosure, is shown in FIG. 7.

FIG. 7 is a process flow diagram illustrating a method for constructing a radio frequency (RF) switch, according to various aspect of the present disclosure. A method 700 begins at block 702, in which a two-dimensional (2D) gate array is formed surrounding a plurality of source/drain regions and a plurality of drain/source regions. For example, as shown in FIG. 4, the waffle-shaped RF switch 400 includes the 2D gate array 420 surrounding source(S) regions and drain (D) regions. In this configuration, the 2D gate array 420 includes a frontside (shown) and a backside (not show) opposite the frontside.

At block 704, backside source/drain contacts are formed to couple the plurality of source/drain regions at a backside of the 2D gate array. For example, as shown in FIG. 4, the waffle-shaped RF switch 400 includes the backside source contacts 430 coupled to the source(S) regions at the backside of the 2D gate array 420. Additionally, the waffle-shaped RF switch 400 includes the frontside drain contacts 410 coupled to the drain (D) regions at the frontside of the 2D gate array 420.

At block 706, backside metallization layers are formed to couple to the backside source/drain contacts. Additionally, at block 708, frontside drain/source contacts are formed to couple the plurality of drain/source regions at a frontside, opposite the backside, of the 2D gate array. For example, as shown in FIG. 4, the waffle-shaped RF switch FET 400 includes frontside drain contacts 410 coupled to the drain (D) regions at the frontside of the 2D gate array 420. In this example, the frontside drain contacts 410 are contacted to frontside metallization layers 440, and the backside source contacts 430 are contacted to backside metallization layers 450, as further illustrated in FIG. 5A-5C.

At block 710, form frontside metallization layers coupled to the frontside drain/source contacts. For example, connections between the frontside metallization layers 440 to the frontside drain contacts 410 are further illustrated in FIG. 5A. In this example, the frontside metallization layers 440 are composed of middle-of-line (MOL) zero interconnect layers, including metal zero (M0) interconnect connections to the frontside drain contacts 410, followed by a zero via (V0) to back-end-of-line (BEOL) layers. The BEOL layers includes a first metal (M1) interconnect coupled to a first metal via (V1), and a second metal (M2) interconnect, followed by a second metal via (V2) connection to a third metal (M3) interconnect, which may be extended to outside bus lines. In this example, interconnects to drain (D) or source(S) regions are separated by the frontside metallization layers 440, or the backside metallization layers 450.

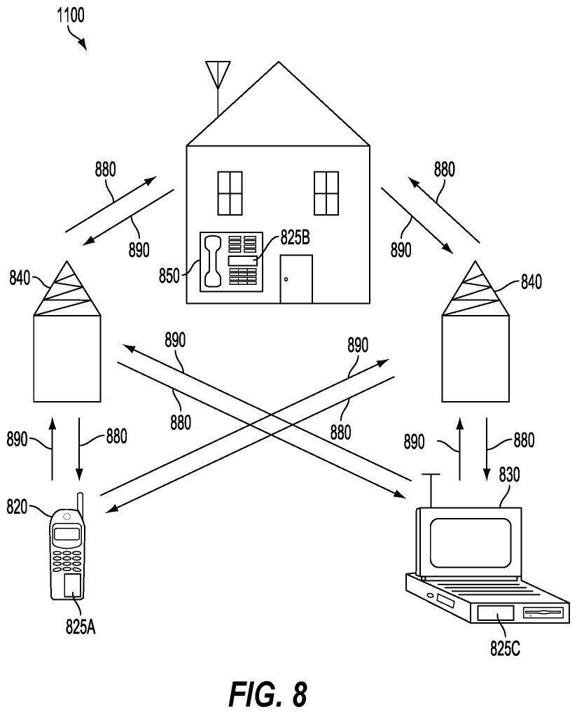

FIG. 8 is a block diagram showing an exemplary wireless communications system 800 in which an aspect of the present disclosure may be advantageously employed. For purposes of illustration, FIG. 8 shows three remote units 820, 830, and 850 and two base stations 840. It will be recognized that wireless communications systems may have many more remote units and base stations. Remote units 820, 830, and 850 include IC devices 825A, 825C, and 825B that include the disclosed waffle-shaped switch field effect transistors (FETs). It will be recognized that other devices may also include the disclosed waffle-shaped switch field effect transistors (FETs), such as the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 8 illustrates remote units, according to the aspects of the present disclosure, the present disclosure is not limited to these exemplary illustrated units. Aspects of the present disclosure may be suitably employed in many devices, which include the disclosed waffle-shaped switch field effect transistors (FETs).

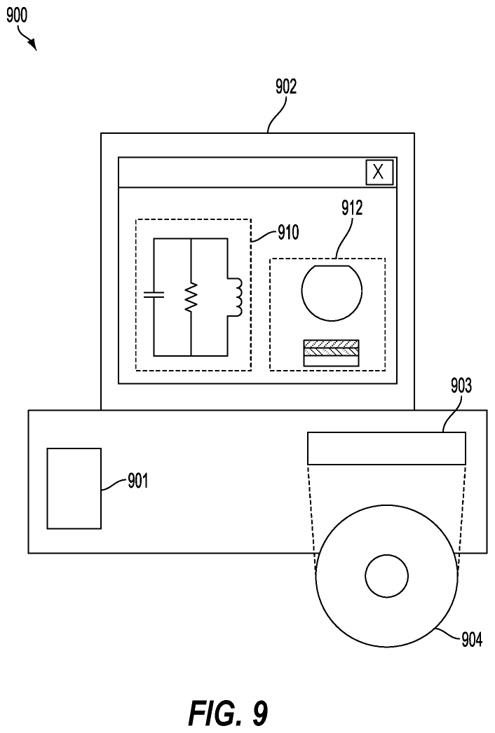

FIG. 9 is a block diagram illustrating a design workstation used for circuit, layout, and logic design of a semiconductor component, such as the waffle-shaped switch field effect transistors (FETs) disclosed above. A design workstation 900 includes a hard disk 901 containing operating system software, support files, and design software such as Cadence or OrCAD. The design workstation 900 also includes a display 902 to facilitate a circuit design 910 or an RFIC 912. A storage medium 904 is provided for tangibly storing the circuit design 910 or the RFIC 912. The circuit design 910 or the RFIC 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit design 910 or the RFIC 912 by decreasing the number of processes for designing semiconductor wafers.

Implementation examples are described in the following numbered clauses:

1. A radio frequency (RF) switch, comprising:
a two-dimensional (2D) gate array surrounding a plurality of source/drain regions and a plurality of drain/source regions;
backside source/drain contacts coupled to the plurality of source/drain regions at a backside of the 2D gate array;
backside metallization layers coupled to the backside source/drain contacts;
frontside drain/source contacts coupled to the plurality of drain/source regions at a frontside, opposite the backside, of the 2D gate array; and
frontside metallization layers coupled to the frontside drain/source contacts.

2. The RF switch of clause 1, in which the frontside metallization layers comprise:
middle-of-line (MOL) metallization layers coupled to the frontside drain/source contacts; and
back-end-of-line (BEOL) metallization layers coupled to the MOL metallization layers.

3. The RF switch of clause 2, in which the MOL metallization layers comprise a plurality of zero vias (V0) coupled to the frontside drain/source contacts.

4. The RF switch of any of clauses 1-3, in which the backside metallization layers comprise middle-of-line (MOL) metallization layers coupled to the backside source/drain contacts.

5. The RF switch of any of clauses 1-4, further comprising a backside gate coupled to the 2D gate array.

6. The RF switch of any of clauses 1-5, further comprising a backside gate coupled to the backside source/drain contacts.

7. The RF switch of any of clauses 1-6, integrated into an RF front end module.

8. The RF switch of clause 7, in which the RF front end module is incorporated in at least one of a music player, a video player, an entertainment unit, a navigation device, a communications device, a personal digital assistant (PDA), a fixed location data unit, a mobile phone, and a portable computer.

9. A method of constructing a radio frequency (RF) switch, the method comprising:
forming a two-dimensional (2D) gate array surrounding a plurality of source/drain regions and a plurality of drain/source regions;
forming backside source/drain contacts coupled to the plurality of source/drain regions at a backside of the 2D gate array;
forming backside metallization layers coupled to the backside source/drain contacts;
forming frontside drain/source contacts coupled to the plurality of drain/source regions at a frontside, opposite the backside, of the 2D gate array; and
forming frontside metallization layers coupled to the frontside drain/source contacts.

10. The method of clause 9, in which forming the frontside metallization layers comprises:
forming middle-of-line (MOL) metallization layers coupled to the frontside drain/source contacts; and
forming back-end-of-line (BEOL) metallization layers coupled to the MOL metallization layers.

11. The method of clause 10, in which the MOL metallization layers comprise a plurality of zero vias (V0) coupled to the frontside drain/source contacts.

12. The method of any of clauses 9-11, in which forming the backside metallization layers comprises forming middle-of-line (MOL) metallization layers coupled to the backside source/drain contacts.

13. The method of any of clauses 9-12, further comprising forming a backside gate coupled to the 2D gate array.

14. The method of any of clauses 9-13, further comprising forming a backside gate coupled to the backside source/drain contacts.

15. The method of any of clauses 9-14, further comprising integrating the RF switch into an RF front end module.

16. The method of clause 15, further comprising incorporating the RF front end module in at least one of a music player, a video player, an entertainment unit, a navigation device, a communications device, a personal digital assistant (PDA), a fixed location data unit, a mobile phone, and a portable computer.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described herein may be utilized, according to the present disclosure. Accordingly, the appended claims are intended to include within their scope such processes, machines, manufacture, compositions of matter, means, methods, or steps.

What is claimed is:

1. A radio frequency (RF) switch, comprising:
a two-dimensional (2D) gate array surrounding a plurality of source/drain regions and a plurality of drain/source regions;
backside source/drain contacts coupled to the plurality of source/drain regions at a backside of the 2D gate array;
backside metallization layers coupled to the backside source/drain contacts;
frontside drain/source contacts coupled to the plurality of drain/source regions at a frontside, opposite the backside, of the 2D gate array; and
frontside metallization layers coupled to the frontside drain/source contacts.

2. The RF switch of claim 1, in which the frontside metallization layers comprise:
middle-of-line (MOL) metallization layers coupled to the frontside drain/source contacts; and
back-end-of-line (BEOL) metallization layers coupled to the MOL metallization layers.

3. The RF switch of claim 2, in which the MOL metallization layers comprise a plurality of zero vias (V0) coupled to the frontside drain/source contacts.

4. The RF switch of claim 1, in which the backside metallization layers comprise middle-of-line (MOL) metallization layers coupled to the backside source/drain contacts.

5. The RF switch of claim 1, further comprising a backside gate coupled to the 2D gate array.

6. The RF switch of claim 1, further comprising a backside gate coupled to the backside source/drain contacts.

7. The RF switch of claim 1, integrated into an RF front end module.

8. The RF switch of claim 7, in which the RF front end module is incorporated in at least one of a music player, a video player, an entertainment unit, a navigation device, a communications device, a personal digital assistant (PDA), a fixed location data unit, a mobile phone, and a portable computer.

9. A method of constructing a radio frequency (RF) switch, the method comprising:
forming a two-dimensional (2D) gate array surrounding a plurality of source/drain regions and a plurality of drain/source regions;
forming backside source/drain contacts coupled to the plurality of source/drain regions at a backside of the 2D gate array;
forming backside metallization layers coupled to the backside source/drain contacts;
forming frontside drain/source contacts coupled to the plurality of drain/source regions at a frontside, opposite the backside, of the 2D gate array; and
forming frontside metallization layers coupled to the frontside drain/source contacts.

10. The method of claim 9, in which forming the frontside metallization layers comprises:
forming middle-of-line (MOL) metallization layers coupled to the frontside drain/source contacts; and
forming back-end-of-line (BEOL) metallization layers coupled to the MOL metallization layers.

11. The method of claim 10, in which the MOL metallization layers comprise a plurality of zero vias (V0) coupled to the frontside drain/source contacts.

12. The method of claim 9, in which forming the backside metallization layers comprises forming middle-of-line (MOL) metallization layers coupled to the backside source/drain contacts.

13. The method of claim 9, further comprising forming a backside gate coupled to the 2D gate array.

14. The method of claim 9, further comprising forming a backside gate coupled to the backside source/drain contacts.

15. The method of claim 9, further comprising integrating the RF switch into an RF front end module.

16. The method of claim 15, further comprising incorporating the RF front end module in at least one of a music player, a video player, an entertainment unit, a navigation device, a communications device, a personal digital assistant (PDA), a fixed location data unit, a mobile phone, and a portable computer.
